(19) United States
(12) Patent Application Publication
(10) Pub. No.: US 2026/0255909 A1
(43) Pub. Date: Aug. 27, 2026

(54) SUBSTRATE PROCESSING APPARATUS INCLUDING CATALYST PAD

(71) Applicant: Samsung Electronics Co., Ltd., Suwon-si (KR)

(72) Inventor: Shumpei Umeda, Yokohama-shi (JP)

(73) Assignee: Samsung Electronics Co., Ltd., Suwon-si (KR)

(21) Appl. No.: 19/531,320

(22) Filed: Feb. 5, 2026

(30) Foreign Application Priority Data
Feb. 5, 2025 (JP) 2025-017274

(51) Int. Cl. H10P 72/00; B24B 37/04; B24B 37/34

(52) U.S. Cl. CPC H10P 72/0426; B24B 37/04; B24B 37/345; H10P 72/0428

(57) ABSTRACT

A substrate processing apparatus includes: a substrate holding head, a substrate holder provided on the substrate holding head and configured to hold a substrate; a catalyst pad including a base material and a catalyst layer formed on a surface of the base material facing the substrate, the catalyst layer having a substrate contact surface that contacts a processing surface of the substrate; a pad holder configured to fixedly hold the catalyst pad inside a process chamber; a supply and discharge unit configured to supply at least an etching processing solution into the process chamber; a transfer mechanism configured to relatively move the substrate holding head with respect to the catalyst pad in a contact/separation direction; and a control unit. The supply and discharge unit supplies fresh processing solution to the substrate contact surface while the processing surface of the substrate is pressed against the substrate contact surface.

### CROSS-REFERENCE TO RELATED APPLICATION

This present application claims priority to and the benefit under 35 U.S.C. § 119(a)-(d) of Japanese Patent Application No. 2025-017274, filed on Feb. 5, 2025, in the Japan Patent Office, the entire disclosure of which is incorporated herein by reference.

### FIELD

The present disclosure relates to a substrate processing apparatus and more particularly to a substrate processing apparatus including a catalyst pad.

### BACKGROUND

In general, chemical-mechanical polishing (CMP) is used in the substrate planarization process for a semiconductor device. CMP is a wet polishing technique that combines chemical action and mechanical polishing. However, concerns arise regarding the effects on product quality caused by the occurrence of scratches due to mechanical polishing and particles generated by slurry.

Patent Literature 1 (JP 2018-174229) discloses a substrate processing apparatus that planarizes a substrate to be processed by using catalyst-referred etching (CARE), which is one type of etching method employing a catalyst. The substrate processing apparatus of Patent Literature 1 includes a CARE head having a pad holding portion (substrate holding portion) for holding the substrate and a catalyst holding portion for holding a catalyst. The catalyst holding portion includes a high-rigidity base plate, a piezoelectric element arranged adjacent to the base plate, a high-rigidity catalyst holding base arranged adjacent to the piezoelectric element, and a catalyst held on the catalyst holding base. The substrate processing apparatus further includes a control device for controlling an operating voltage applied to the piezoelectric element.

### SUMMARY

(1) A substrate processing apparatus etches a processing surface of a substrate to be processed inside a process chamber and includes: a substrate holding head; a substrate holder provided on the substrate holding head and configured to hold the substrate; a catalyst pad including a base material and a catalyst layer formed on a surface of the base material facing the substrate, the catalyst layer having a substrate contact surface that contacts the processing surface of the substrate; a pad holder configured to fixedly hold the catalyst pad inside the process chamber; a supply and discharge unit configured to supply at least an etching processing solution into the process chamber; a transfer mechanism configured to relatively move the substrate holding head with respect to the catalyst pad in a contact/separation direction along which the substrate holding head approaches and separates from the catalyst pad; and a control unit, wherein the catalyst pad has a substrate contact surface whose area is larger than that of the processing surface, and the supply and discharge unit supplies fresh processing solution to the substrate contact surface while the processing surface of the substrate is pressed against the substrate contact surface of the catalyst pad, in the presence of the processing solution supplied into the process chamber.
(2) In the substrate processing apparatus described above in (1), the substrate holding head may be fixed in position while the processing surface of the substrate is in contact with the substrate contact surface of the catalyst layer.
(3) In the substrate processing apparatus described above in (1), a flatness of the substrate contact surface may be greater than a flatness of the processing surface.
(4) In the substrate processing apparatus described above in any one of (1) to (3), the supply and discharge unit may include: a first supply and discharge unit that supplies the processing solution into the process chamber; and a second supply and discharge unit that supplies the processing solution to the substrate contact surface through an interior of the catalyst pad.
(5) In the substrate processing apparatus described above in (4), the pad holder may have a fixing surface fixed to the process chamber, and the second supply and discharge unit may include: a plurality of supply holes communicating with the substrate contact surface and the fixing surface; a supply/discharge line that supplies the processing solution to the supply holes; and a flow controller that controls an amount of processing solution supplied to the supply holes.
(6) In the substrate processing apparatus described above in any one of (1) to (5), the substrate holding head may be provided with a thickness measuring unit that measures thickness of the substrate.
(7) In the substrate processing apparatus described above in any one of (1) to (6), the transfer mechanism may include an adjustment drive unit that moves the substrate holding head substantially in the contact/separation direction, in a planar direction substantially orthogonal to the contact/separation direction, and in a rotational direction using the contact/separation direction as a rotation axis.
(8) In the substrate processing apparatus described above in (7), the control unit may move the substrate holding head in a separation direction to separate the substrate contact surface from the processing surface, then move the substrate holding head substantially in at least one of the planar direction and the rotational direction, and then move the substrate holding head in a contact direction to bring the substrate contact surface into contact with the processing surface.
(9) In the substrate processing apparatus described above in (7) or (8), a predetermined transfer pattern may be formed on the substrate contact surface, and the control unit may drive the transfer mechanism so that an arbitrary pattern shape corresponding to the transfer pattern is formed on the processing surface.
(10) In the substrate processing apparatus described above in any one of (1) to (9), the substrate processing apparatus may further include a conditioning mechanism that conditions the substrate contact surface of the catalyst pad.
(11) In the substrate processing apparatus described above in any one of (1) to (10), the catalyst layer may be formed of a precious metal or a carbon material.
(12) In the substrate processing apparatus described above in any one of (1) to (10), the control unit may control an amount of processing solution supplied from the supply and discharge unit based on thickness information of the substrate measured by the thickness measuring unit.

### BRIEF DESCRIPTION OF THE DRAWINGS

The above and other aspects and features of the present disclosure will become more apparent by describing exemplary embodiments thereof in detail with reference to the attached drawings, in which:

FIG. 1 is a schematic diagram illustrating the configuration of a substrate processing apparatus according to embodiments of the present disclosure;

FIG. 2 is a functional block diagram of a supply and discharge unit of the substrate processing apparatus according to embodiments;

FIG. 3A is a diagram illustrating the flow of planarization processing of the substrate processing apparatus according to embodiments;

FIG. 3B is a diagram illustrating the flow of planarization processing of the substrate processing apparatus according to embodiments;

FIG. 3C is a diagram illustrating the flow of planarization processing of the substrate processing apparatus according to embodiments;

FIG. 3D is a schematic diagram illustrating an example of a reaction process of wet etching employing a catalyst used in the present disclosure;

FIG. 4A is a diagram illustrating an example of the shape of a substrate;

FIG. 4B is a diagram illustrating another example of the shape of a substrate;

FIG. 4C is a diagram illustrating another example of the shape of a substrate;

FIG. 5 is a diagram illustrating an example of the configuration of a conditioning mechanism;

FIG. 6 is a flowchart illustrating the flow of planarization processing performed in the substrate processing apparatus according to embodiments;

FIG. 7A shows schematic diagrams illustrating the operation of the substrate processing apparatus according to embodiments;

FIG. 7B shows schematic diagrams illustrating the operation of the substrate processing apparatus according to embodiments;

FIG. 8 is a schematic diagram of a substrate processing apparatus according to embodiments of the present disclosure;

FIG. 9 is a functional block diagram of a supply and discharge unit of the substrate processing apparatus according to embodiments;

FIG. 10A is a diagram illustrating an example of the formation of a supply hole;

FIG. 10B is a diagram illustrating another example of the formation of a supply hole;

FIG. 11A is a diagram illustrating planarization processing of a surface irregularity portion that has entered a supply hole of the substrate processing apparatus according to embodiments;

FIG. 11B is a diagram illustrating planarization processing of the surface irregularity portion that has entered the supply hole of the substrate processing apparatus according to embodiments;

FIG. 12A is a schematic cross-sectional view illustrating a substrate rotation processing operation of the substrate processing apparatus according to embodiments;

FIG. 12B is a schematic cross-sectional view illustrating a substrate rotation processing operation of the substrate processing apparatus according to embodiments;

FIG. 12C is a schematic cross-sectional view illustrating a substrate rotation processing operation of the substrate processing apparatus according to embodiments;

FIG. 13 is a flowchart illustrating a series of flows of planarization processing performed in the substrate processing apparatus according to embodiments;

FIG. 14 shows schematic diagrams illustrating the operation of the substrate processing apparatus according to embodiments;

FIG. 15 is a schematic cross-sectional view of a catalyst pad included in the configuration of a substrate processing apparatus according to Modified Example 1;

FIG. 16A is a schematic cross-sectional view illustrating the flow of transfer pattern formation using a catalyst pad of Modified Example 1;

FIG. 16B is a schematic cross-sectional view illustrating the flow of transfer pattern formation using the catalyst pad of Modified Example 1;

FIG. 16C is a schematic cross-sectional view illustrating the flow of transfer pattern formation using the catalyst pad of Modified Example 1; and

FIG. 17 is a schematic cross-sectional view of a substrate processing apparatus according to Modified Example 2.

### DETAILED DESCRIPTION

Hereinafter, embodiments of the present disclosure will be described in detail with reference to the accompanying drawings. In the drawings below, the same reference numerals denote the same components, and the sizes of the respective components may be exaggerated in the drawings for clarity and convenience of explanation. In addition, the embodiments described below are merely illustrative, and various modifications can be made thereto.

In the following description, portions described as “upper” or “above” may include not only being directly above in contact, but also being above in a non-contact state. Similarly, portions described as “lower” or “below” may include not only being directly below in contact, but also being below in a non-contact state.

Unless the context clearly indicates otherwise, a singular expression encompasses the plural. In addition, when a portion is described as “including,” “comprising,” or “having” a particular component, this does not mean excluding other components unless specifically stated otherwise, but means that other components can also be further included.

Unless explicitly described or stated otherwise, steps constituting a method are executed in an appropriate order, but not necessarily limited to the described order. All examples and uses of exemplary terms are merely for describing the technical idea of the present disclosure and, unless limited by the claims, are not to be construed as limiting the scope of the present disclosure.

Meanwhile, in the following description, when ordinals such as “first” and “second” are used, they are used for convenience unless otherwise specified, and do not prescribe any order.

Since the substrate processing apparatus of Patent Literature 1 polishes the surface to be processed by CARE while controlling the distance between the catalyst and the surface to be processed with the piezoelectric element, relative sliding occurs between the catalyst and the surface to be processed due to mechanical vibration of the catalyst. As a result, the substrate processing apparatus of Patent Literature 1 presents concerns such as scratches caused by friction between the surface of the catalyst and the surface to be processed.

In addition, in the apparatus of Patent Literature 1, the contact area of the CARE head with the surface to be processed is smaller than the area of the substrate surface to be processed. Accordingly, in order to process the entire surface to be processed, the CARE head must be moved multiple times within the processing region, leaving room for improvement in terms of productivity.

Furthermore, catalyst-based etching such as CARE is performed in the presence of a processing agent, so the concentration of the processing liquid between the catalyst and the substrate gradually decreases from the start of processing. As a result, catalyst-based wet etching suffers from a problem in that the processing rate gradually slows down and the processing time becomes prolonged.

A substrate processing apparatus 1 according to embodiments of the present disclosure will now be described. According to the present disclosure, productivity can be improved while reducing the occurrence of scratches and the like.

Here, for convenience of explanation, an XYZ orthogonal coordinate system is set in the substrate processing apparatus 1. In a predetermined plane, a direction parallel to the X-axis is defined as an X-axis direction, a direction parallel to the Y-axis, which is orthogonal to the X-axis, is defined as a Y-axis direction, and a direction parallel to the Z-axis, which is orthogonal to each of the X-axis and Y-axis, is defined as a Z-axis direction. The predetermined plane is parallel to a horizontal plane, and is defined as the XY plane, and the Z-axis direction is a vertical direction orthogonal to the predetermined plane. Accordingly, the Z-axis direction is the contact/separation direction (thickness direction of each component) in which a substrate holding head 20 and a catalyst pad 30 approach and separate, and the X- and Y-axis directions correspond to planar directions orthogonal to the contact/separation direction. Meanwhile, the contact/separation direction includes a “separation direction,” in which a substrate contact surface 32a is moved away from a processing surface W1, and a “contact direction,” in which the substrate holding head 20 is moved to bring the substrate contact surface 32a into contact with the processing surface W1.

The substrate processing apparatus 1 is an apparatus that performs various processing operations such as planarization on a processing surface W1 of a substrate W, such as a wafer to be processed into a semiconductor chip, by using a wet etching technique employing a catalyst as an etching process. Meanwhile, the substrate processing apparatus 1 may be configured to perform substrate treatments other than planarization.

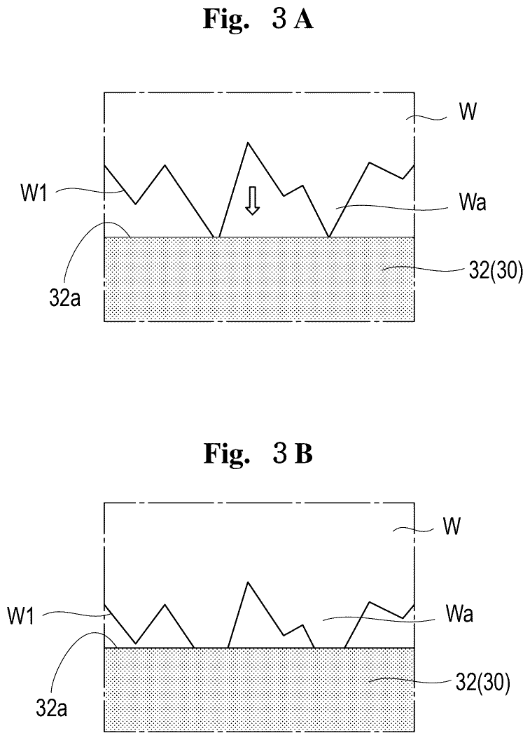

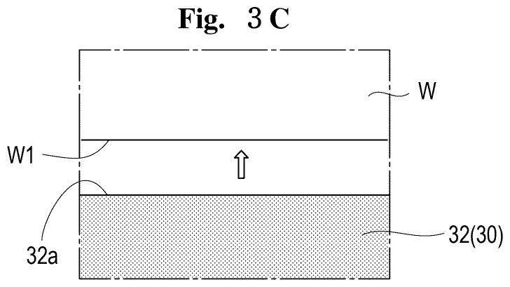

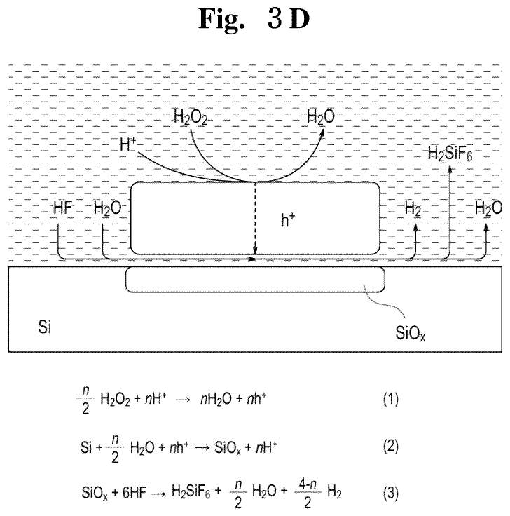

The substrate W, which is the processing target of the substrate processing apparatus 1, may be a wafer formed using, for example, silicon (Si), germanium (Ge), or a group III-V compound semiconductor (e.g., gallium arsenide (GaAs), indium phosphide (InP), gallium phosphide (GaP), indium arsenide (InAs), indium antimonide (InSb), indium gallium arsenide (InGaAs), or a combination thereof). The substrate W has a minute uneven shape, i.e., surface irregularity portions Wa (in FIG. 3A), on its processing surface W1. The surface irregularity portions Wa are portions to be removed by etching. The substrate W is immersed in a processing solution inside a process chamber 10 while its processing surface W1 is in contact with a substrate contact surface 32a of a catalyst pad 30. Accordingly, the surface irregularity portions Wa are removed, achieving planarization.

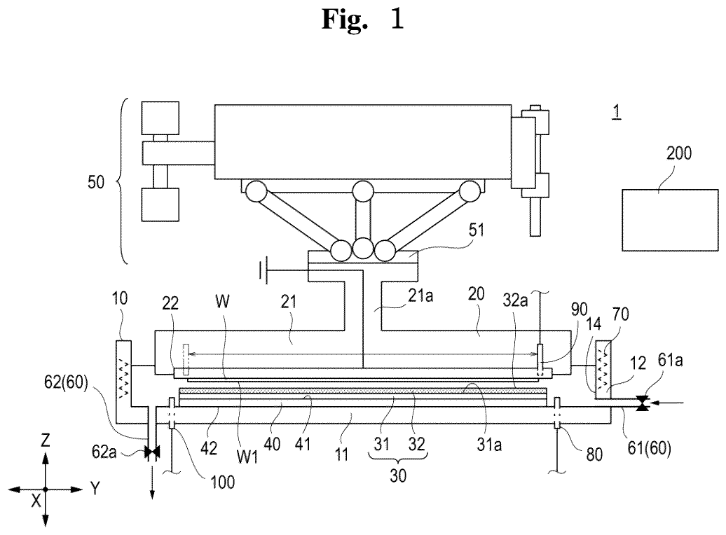

Referring to FIG. 1, the substrate processing apparatus 1 includes the process chamber 10, the substrate holding head 20, the catalyst pad 30, a pad holder 40, a transfer mechanism 50 that moves the substrate holding head 20 in a predetermined direction, a supply and discharge unit 60, a temperature controller 70, a concentration measuring unit 80, and a thickness measuring unit 90. The substrate processing apparatus 1 further includes a control unit 200 illustrated in FIG. 1, and the components of the substrate processing apparatus 1 are driven and controlled by the control unit 200. The substrate processing apparatus 1 may further include other components in addition to the above-mentioned components.

The process chamber 10 includes a bottom portion 11 and a sidewall 12, and has a receiving portion 14 in which a processing solution can be stored. The pad holder 40 is fixedly provided on the bottom portion 11 of the process chamber 10. The temperature controller 70 for maintaining the temperature of the processing solution in the process chamber 10 at a predetermined temperature (e.g., 25° C.) is arranged in the process chamber 10. In FIG. 1, the process chamber 10 may be configured in an open-top cylindrical shape, with the shape of the receiving portion 14 corresponding to that of the substrate W. However, the process chamber 10 may have other shapes such as a rectangular parallelepiped.

The substrate holding head 20 includes a head body 21 and a substrate holder 22. The substrate holding head 20 is arranged at a position facing the pad holder 40. The head body 21 of the substrate holding head 20 is connected to the transfer mechanism 50, and moves relative to the pad holder 40 in the contact/separation direction (Z-axis direction), which is the direction of approach and separation therefrom.

The substrate holder 22 is configured as an electrostatic chuck that adsorptively holds the substrate W. A high voltage required to electrostatically adsorb and fix the substrate W is applied to the substrate holder 22 from a DC power source (not illustrated). Since the substrate holder 22 is configured as an electrostatic chuck, the substrate holder 22 can reliably hold the substrate W immersed in the processing solution inside the process chamber 10.

The catalyst pad 30 includes a base material 31 and a catalyst layer 32. The substrate contact surface 32a of the catalyst pad 30 has an area larger than the area of the processing surface W1 of the substrate W. Accordingly, during planarization, the catalyst pad 30 may come into contact with the entire processing surface W1 of the substrate W. Therefore, the substrate processing apparatus 1 may planarize the entire processing surface W1 in a state where the substrate W and the catalyst pad 30 are fixed in position during etching.

The base material 31 may be formed of, for example, urethane, epoxy resin, or a nonwoven fabric processed from polyester. The Shore D hardness of the base material 31 is 50 or more and 90 or less. The base material 31 has a catalyst formation surface 31a on which the catalyst layer 32 is formed. The catalyst pad 30 is fixed and held by the pad holder 40 so that the base material 31 does not move during processing.

The catalyst layer 32 may be formed of a precious metal such as gold (Au), platinum (Pt), silver (Ag), or ruthenium (Ru), or a carbon material such as fullerene, carbon nanotubes, graphene, graphene nanoribbons, or reduced graphene oxide. The catalyst layer 32 has the substrate contact surface 32a that comes into contact with the processing surface W1 of the substrate W. The substrate contact surface 32a is a surface facing the processing surface W1 of the substrate W held by the substrate holding head 20 when the catalyst pad 30 is placed on the pad holder 40.

When the catalyst layer 32 is formed of a precious metal, it may be formed on the base material 31 by a thin-film forming method such as sputtering. Alternatively, the catalyst layer 32 may be formed by first forming a metal film on the catalyst formation surface 31a, then performing iodine coating, and then applying a pulse electric field in a solvent containing a precursor of the carbon material to deposit a carbon material on the base material 31.

The substrate contact surface 32a is generally flat in order to planarize the processing surface W1. The flatness of the substrate contact surface 32a is greater than that of the processing surface W1 of the substrate W before processing. Accordingly, the surface of the substrate contact surface 32a has overall global flatness superior to that of the processing surface W1 of the substrate W. For example, when the global step height of a 12-inch Si wafer used as the substrate W is 100 nm, the global step height of the substrate contact surface 32a may be less than 100 nm. Meanwhile, as indices of “flatness” in this specification, indices such as Global Backsurface-referenced Ideal plane/Range (GBIR) and Site Backsurface-referenced Ideal plane/Range (SBIR) may be used. Then, these flatness values may be measured in the nano- to micro-order range using a film thickness measuring device employing spectral interferometry.

The pad holder 40 is fixedly arranged on the bottom portion 11 of the process chamber 10, and fixedly holds the catalyst pad 30 at a position facing the substrate holding head 20. The pad holder 40 has a holding surface 41 that holds the catalyst pad 30, and a fixing surface 42 on the opposite side of the holding surface 41.

The transfer mechanism 50 moves the substrate holding head 20 relative to the catalyst pad 30 in the contact/separation direction. The transfer mechanism 50 may be configured, for example, as a six-axis drive mechanism. The transfer mechanism 50 is mounted on a shaft portion 21a of the head body 21 of the substrate holding head 20. The transfer mechanism 50 may include an adjustment drive unit 51 that moves the substrate holding head 20 in the contact/separation direction, in a planar direction (e.g., the X- or Y-axis direction) orthogonal to the contact/separation direction, and in a rotational direction (e.g., a rotational direction OZ around the Z-axis) using the contact/separation direction as a rotation axis. In addition, as another moving direction, the transfer mechanism 50 may move the substrate holding head 20 in a rotational direction OX around the X-axis and a rotational direction OY around the Y-axis by driving the adjustment drive unit 51. However, as a function of the adjustment drive unit 51, the transfer mechanism 50 may also be configured as a drive mechanism that moves the substrate holding head 20 only in the contact/separation direction (separation direction and contact direction along the Z-axis) rather than freely in all of the above directions.

The transfer mechanism 50 moves the substrate holding head 20 in the contact/separation direction while maintaining the processing surface W1 of the substrate W parallel to the planar direction (e.g., the X- or Y-axis direction) orthogonal to the contact/separation direction. At this time, when the substrate W comes into contact with the substrate contact surface 32a of the catalyst layer 32, substantially uniform pressing force is applied to the entire processing surface W1. While the substrate W and the catalyst pad 30 are in contact, the transfer mechanism 50 applies only a pressing force to the substrate holding head 20. Accordingly, during etching, the substrate W does not move in the planar direction.

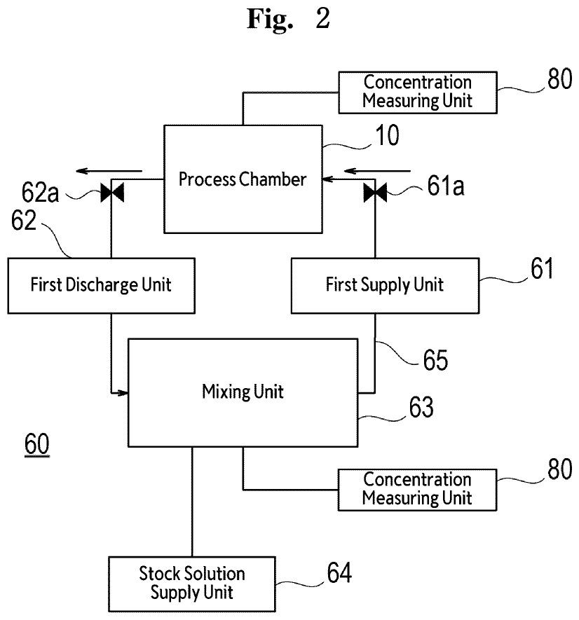

The supply and discharge unit 60 supplies a predetermined amount of processing solution into the process chamber 10. Referring to FIG. 2, the supply and discharge unit 60 includes a first supply unit 61, a first discharge unit 62, a mixing unit 63, and a stock solution supply unit 64. The supply and discharge unit 60 may be configured such that the processing solution flows through each unit via piping 65. The supply and discharge unit 60 is operated under the control of the control unit 200. The first supply unit 61, the first discharge unit 62, the mixing unit 63, and the stock solution supply unit 64 may function as a first supply and discharge unit that supplies processing solution into the process chamber 10.

The supply and discharge unit 60 performs supply and discharge of processing solution into and from the process chamber 10 via the first supply unit 61, the first discharge unit 62, and the mixing unit 63, and constitutes a circulation path for storing a predetermined amount of processing solution in the process chamber 10.

The processing solution supplied by the supply and discharge unit 60 is a fluid such as a liquid, and may be, for example, a mixed solution of hydrofluoric acid (HF), hydrogen peroxide (H₂O₂), pure water (H₂O), and an amine-based additive. With a mixing ratio (volume ratio) of HF:H₂O₂:H₂O=1:1:X, or a molar ratio of 1 M:1.3 M:X, stable etching may be performed. When lower processing speed is desired to increase controllability, the pure water ratio X may be increased. From the perspective of improving stability, such as suppression of porous Si formation, it is effective to add a small amount of an amine-based polymer additive or a surfactant.

The first supply unit 61 supplies a predetermined amount of processing solution supplied from the mixing unit 63 into the process chamber 10. The first supply unit 61 is formed so as to penetrate the sidewall 12 of the process chamber 10. A supply amount controller 61a such as a valve is provided on the upstream side of the first supply unit 61. The supply amount controller 61a is opened and closed under the control of the control unit 200 so that a predetermined amount of processing solution is stored in the process chamber 10.

The first discharge unit 62 discharges a predetermined amount of processing solution in the process chamber 10. The first discharge unit 62 is formed so as to penetrate the bottom portion 11 of the process chamber 10. The first discharge unit 62 circulates the discharged processing solution to the mixing unit 63. A discharge amount controller 62a such as a valve is provided on the downstream side of the first discharge unit 62. The discharge amount controller 62a is opened and closed under the control of the control unit 200 so that a predetermined amount of processing solution is stored in the process chamber 10.

The mixing unit 63 temporarily stores the processing solution discharged through the first discharge unit 62, and circulates a predetermined amount of processing solution to the first supply unit 61. At a timing when the concentration of the processing solution falls below a reference, or at a timing when a predetermined amount of time has elapsed after the start of processing, the stock solution of the processing solution is supplied from the stock solution supply unit 64. The mixing unit 63 functions as a buffer for keeping the concentration of the processing solution constant.

The stock solution supply unit 64 is a tank that stores the stock solution of the processing solution. The stock solution supply unit 64 supplies the stock solution to the mixing unit 63 at a timing when the concentration of the processing solution falls below a reference, or at a timing when a predetermined amount of time has elapsed after the start of processing. Accordingly, the processing solution stored in the mixing unit 63 is adjusted to a reference concentration by mixing the processing solution introduced from the first discharge unit 62 with the stock solution supplied from the stock solution supply unit 64.

The temperature controller 70 is a heating and cooling device capable of heating and cooling the processing solution stored in the process chamber 10 to a predetermined temperature (e.g., 25° C.). The temperature controller 70 may be provided inside the bottom portion 11 or the sidewall 12 of the process chamber 10 to heat or cool the process chamber 10 and thereby indirectly adjust the temperature of the processing solution. Alternatively, the temperature controller 70 may be arranged so as to be exposed to the inner surface of the bottom portion 11 or the sidewall 12 of the process chamber 10, so that the processing solution is directly heated or cooled for its temperature adjustment.

The concentration measuring unit 80 measures the concentration of the processing solution. As illustrated in FIG. 1, the concentration measuring unit 80 is provided at a position for measuring the concentration of the processing solution in the process chamber 10. The concentration measuring unit 80 measures the concentration of the processing solution in the process chamber 10 and outputs an electrical signal corresponding to the measured concentration to the control unit 200.

The concentration measuring unit 80 may also be provided in the mixing unit 63 to measure the concentration of the processing solution stored in the mixing unit 63. The concentration measuring unit 80 measures the concentration of the processing solution in the mixing unit 63 and outputs an electrical signal corresponding to the measured concentration to the control unit 200.

The thickness measuring unit 90 measures the thickness of the substrate W. The thickness measuring unit 90 may be configured as a non-contact measuring device using, for example, infrared light. The thickness measuring unit 90 is provided so as to be movable in the diameter direction of the substrate W. Accordingly, the thickness measuring unit 90 may measure the thickness of the substrate W as a whole. The thickness measuring unit 90 measures the thickness of the substrate W and outputs an electrical signal corresponding to the measured thickness to the control unit 200.

The temperature measuring unit 100 measures the temperature of the processing solution stored in the process chamber 10. The temperature measuring unit 100 measures the temperature of the processing solution in the process chamber 10 and outputs an electrical signal corresponding to the measured temperature to the control unit 200.

The control unit 200 may be configured, for example, with a processor and a memory that stores programs and information for operating the processor. The control unit 200 performs overall drive control of the components of the substrate processing apparatus 1.

Hereinafter, the main control operation of the control unit 200 will be described. Meanwhile, in addition to the main control operation to be described below, the control unit 200 performs various control operations in connection with the driving of the substrate processing apparatus 1.

The control unit 200 drives and controls the transfer mechanism 50 to move the substrate holding head 20 in a predetermined direction. Under the control of the control unit 200, the substrate holding head 20 moves along the contact/separation direction at a predetermined timing during planarization processing so that the substrate W and the catalyst pad 30 come into contact or are separated.

The control unit 200 drives and controls the first supply unit 61, the first discharge unit 62, and the stock solution supply unit 64 based on measurement data from the concentration measuring unit 80. The mixing unit 63 receives a required amount of stock processing solution from the stock solution supply unit 64, so that the concentration of the processing solution stored therein is adjusted to a reference concentration. The processing solution adjusted in concentration in the mixing unit 63 is supplied into the process chamber 10 through the first supply unit 61. As a result, the processing solution in the process chamber 10 reaches the reference concentration.

The control unit 200 drives and controls the transfer mechanism 50 based on measurement data from the thickness measuring unit 90 to move the substrate holding head 20 in a predetermined direction. For example, when it is determined, based on the measurement data from the thickness measuring unit 90, that the processing surface W1 of the substrate W has been etched to a target thickness, the control unit 200 moves the substrate holding head 20 in the contact/separation direction to separate the substrate W from the catalyst pad 30. In this manner, the substrate processing apparatus 1 terminates the planarization processing of the substrate W. In addition, when it is determined, based on the measurement data from the thickness measuring unit 90, that the etching rate has decreased below a certain level, the control unit 200 moves the substrate holding head 20 in the contact/separation direction to separate the substrate W from the catalyst pad 30. As a result, the processing solution between the center of the substrate W and the center of the catalyst layer 32 is replaced by surrounding fresh processing solution due to a negative pressure effect caused by the separating movement of the substrate holding head 20, and the etching rate may be restored to that at the start of processing.

The control unit 200 performs opening and closing control of the supply amount controller 61a of the first supply unit 61 and the discharge amount controller 62a of the first discharge unit 62, thereby maintaining a constant amount of processing solution stored in the process chamber 10. As a result, a constant amount of processing solution is always stored in the process chamber 10 during planarization processing.

The control unit 200 drives and controls the temperature controller 70 based on measurement data from the temperature measuring unit 100. As a result, the processing solution in the process chamber 10 is maintained at a constant temperature.

Referring to FIGS. 3A to 3C, the substrate processing apparatus 1 planarizes the processing surface W1 of the substrate W by bringing it into contact with the substrate contact surface 32a of the catalyst pad 30 in the presence of a processing solution, using a catalyst-based wet etching method.

Referring to FIG. 3A, when planarization processing begins, part of the processing surface W1 of the substrate W comes into contact with the substrate contact surface 32a.

Referring to FIG. 3B, the surface irregularity portions Wa of the processing surface W1 come into contact with the catalyst layer 32 of the substrate contact surface 32a in the processing solution, and are gradually etched according to the principle shown in FIG. 3D. In embodiments, wet etching first proceeds such that, as illustrated in Chemical Formula (1) below, hydrogen peroxide is reduced by the action of the catalyst, thereby generating holes (h+). Then, as shown in Chemical Formula (2) below, when the holes (h+) are supplied through the catalyst to the surface of the substrate W, Si is oxidized to generate SiO. Then, as shown in Chemical Formula (3) below, the generated SiO reacts with hydrofluoric acid (HF) in the solvent, and etching progresses. During the etching process, both the substrate W and the catalyst pad 30 remain stationary in the planar direction, while contact between the processing surface W1 and the substrate contact surface 32a is maintained under pressing force applied by the transfer mechanism 50. In Chemical Formulas (1) to (3), “H+” denotes a hydrogen ion, “H₂SiF₆” denotes hexafluorosilicic acid, and “n” denotes a coefficient corresponding to an arbitrary number of Si atoms (n=1, 2, 3, 4).

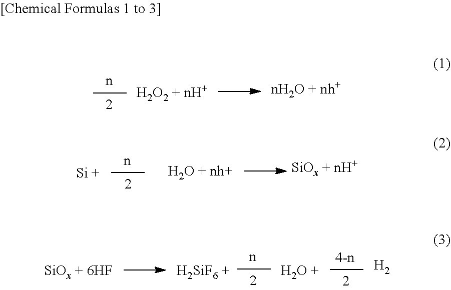

Then, as illustrated in FIG. 3C, when the substrate W is etched for a predetermined amount of time, the processing surface W1 becomes planarized.

In this manner, the substrate processing apparatus 1 performs planarization while maintaining contact between the substrate W and the catalyst pad 30 during etching. Accordingly, since the substrate processing apparatus 1 does not move the substrate holding head 20 in the planar direction during etching, scratches and the like can be prevented. In addition, since the substrate contact surface 32a of the catalyst pad 30 has an area larger than that of the processing surface W1 of the substrate W, the entire processing surface W1 of the substrate W can be planarized at once during planarization, thereby improving productivity.

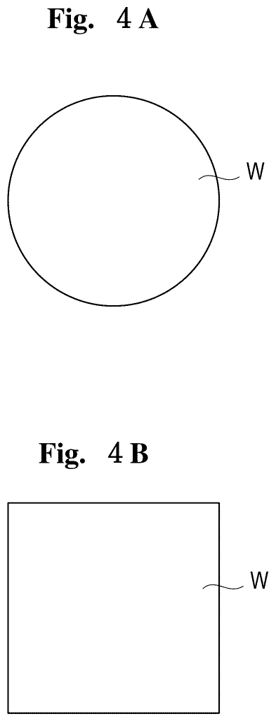

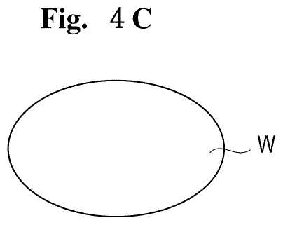

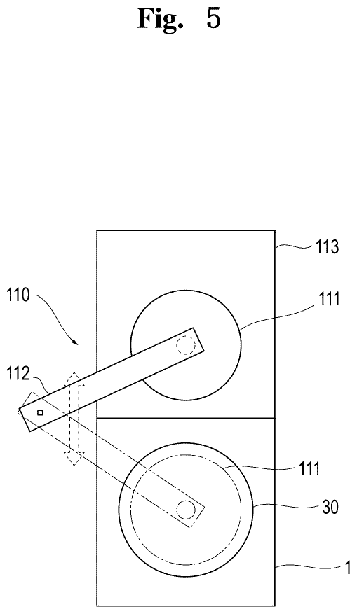

When the processing surface W1 of the substrate W is accommodated within the substrate contact surface 32a of the catalyst pad 30, the substrate processing apparatus 1 may shape the substrate W into a desired shape in plan view. For example, the substrate W may be circular as illustrated in FIG. 4A, rectangular, such as a square, as illustrated in FIG. 4B, or elliptical as illustrated in FIG. 4C, among other shapes.

Referring to FIG. 5, the substrate processing apparatus 1 requires conditioning, such as polishing or replacement of the catalyst pad 30, due to thinning of the substrate contact surface 32a, foreign matter adhesion caused by etching, peeling of the catalyst layer 32, deterioration in flatness, and the like. Accordingly, the substrate processing apparatus 1 includes a conditioning mechanism 110 for performing predetermined conditioning of the catalyst pad 30.

The conditioning mechanism 110 is arranged at a position in the process chamber 10 that provides access to the catalyst pad 30. The conditioning mechanism 110 includes a conditioning portion 111 that performs predetermined conditioning such as polishing on the substrate contact surface 32a of the catalyst pad 30. The conditioning portion 111 may be mounted on an arm 112 and may move between the substrate processing apparatus 1 and a standby portion 113. The conditioning portion 111 normally stands by in the standby portion 113, and when conditioning is to be performed, moves from the standby portion 113 to above the catalyst pad 30 of the substrate processing apparatus 1.

The conditioning mechanism 110 performs conditioning at a timing corresponding to a predetermined conditioning condition, such as a total etching duration or the number of etching cycles, under the control of the control unit 200. Upon the arrival of the timing to perform conditioning, the conditioning mechanism 110 drives the arm 112 to move the conditioning portion 111 from the standby portion 113 to the substrate processing apparatus 1. The conditioning mechanism 110 performs predetermined conditioning on the substrate contact surface 32a of the catalyst pad 30 through the conditioning portion 111. After conditioning the catalyst pad 30, the conditioning mechanism 110 drives the arm 112 to return the conditioning portion 111 to the standby portion 113.

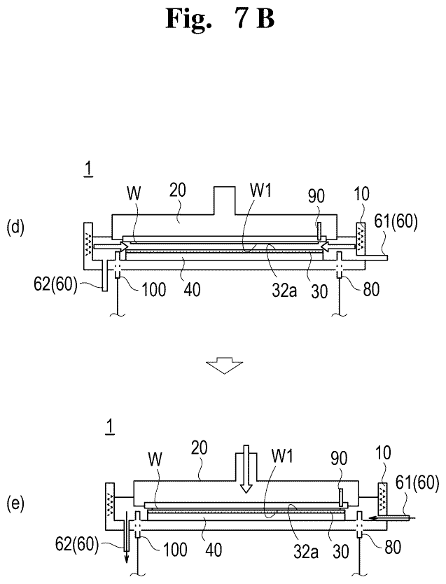

Thereafter, the operation of the substrate processing apparatus 1 according to embodiments will be described with reference to FIGS. 7A and 7B. Meanwhile, a series of steps to be described below are merely exemplary, and other steps may also be included in between as necessary. In addition, the order of the steps to be described below may be changed without departing from the gist of the present disclosure.

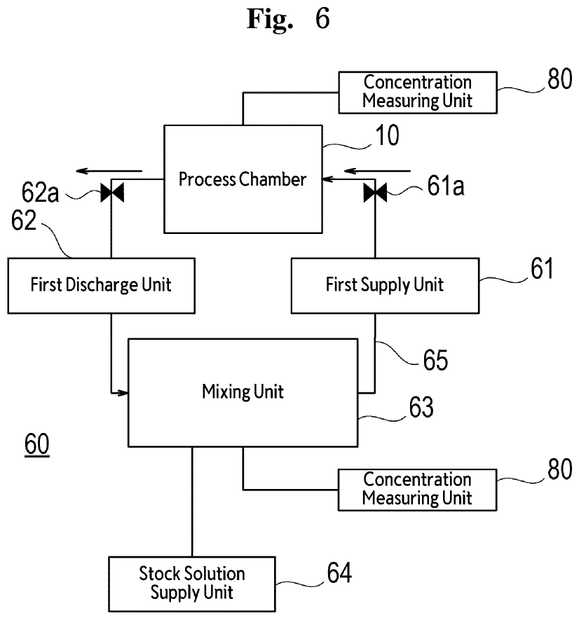

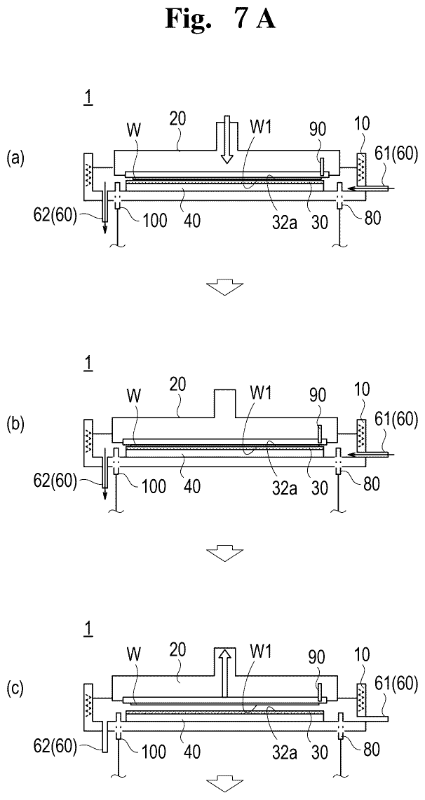

Referring to FIG. 6, the substrate processing apparatus 1 performs processing as planarization processing, including a contact step (S1), a planarization processing step (S2), a first determination step (S3), a processing solution replacement step (S4), and a second determination step (S5). The substrate processing apparatus 1 performs each of these steps by driving each component under the control of the control unit 200.

Meanwhile, the substrate processing apparatus 1 may perform a preparation step before performing the contact step (S1). The preparation step includes, for example, storing a predetermined amount of processing solution in the process chamber 10, setting the substrate W on the substrate holding head 20, and setting the catalyst pad 30 on the pad holder 40.

Referring to FIG. 7A (a), the substrate processing apparatus 1 performs the contact process (S1). The processing surface W1 of the substrate W comes into contact with the substrate contact surface 32a of the catalyst pad 30.

Referring to FIG. 7A (b), the substrate processing apparatus 1 performs the planarization processing step (S2). In the process chamber 10, the substrate W undergoes planarization while being immersed in the processing solution and in contact with the catalyst pad 30.

The substrate processing apparatus 1 performs the first determination step (S3). Based on the measurement data from the thickness measuring unit 90, the control unit 200 determines whether the etching rate has decreased below a certain level and whether the in-plane uniformity deviation of the etching rate has exceeded a certain level. When the control unit 200 determines that the etching rate has decreased below a certain level and that the in-plane uniformity deviation of the etching rate has exceeded a certain level (S3—Yes), the process proceeds to the processing solution replacement step (S4). Meanwhile, when the control unit 200 determines that the etching rate has not decreased below a certain level or that the in-plane uniformity deviation of the etching rate has not exceeded a certain level (S3—No), the substrate processing apparatus 1 returns to the planarization processing step (S2) so that planarization processing continues.

Thereafter, the substrate processing apparatus 1 performs the processing solution replacement step (S4). Referring to FIG. 7A (c), the substrate processing apparatus 1 drives the transfer mechanism 50 to move the substrate holding head 20 by a predetermined distance and separate the substrate W from the catalyst pad 30. Accordingly, referring to FIG. 7B (d), the processing solution between the center of the substrate W and the center of the catalyst layer 32 is replaced by surrounding fresh processing solution due to a negative pressure effect caused by the separating movement of the substrate holding head 20. Referring to FIG. 7B (e), the processing solution replacement step (S4) involves separating the substrate holding head 20 for a predetermined amount of time and then bringing the processing surface W1 back into contact with the substrate contact surface 32a.

Thereafter, the substrate processing apparatus 1 performs the second determination step (S5). The control unit 200 determines, based on the measurement data from the thickness measuring unit 90, whether the substrate W has been etched to a target thickness. When the control unit 200 determines that the substrate W has been etched to the target thickness (S5—Yes), the processing performed by the substrate processing apparatus 1 ends. Meanwhile, when the control unit 200 determines that the substrate W has not been etched to the target thickness (S5—No), the substrate processing apparatus 1 returns to the planarization processing step (S2) so that planarization processing continues.

Hereinafter, a substrate processing apparatus 1A according to embodiments of the present disclosure will be described. In the following description of embodiments, the same reference numerals are assigned to the same configurations as in embodiments described above, and detailed descriptions thereof will be omitted. In addition, features not explicitly mentioned may also be configured in the same manner as in embodiments described above.

The substrate processing apparatus 1A differs from its counterpart of embodiments in the forms of a catalyst pad 30, a pad holder 40, and a supply and discharge unit 60.

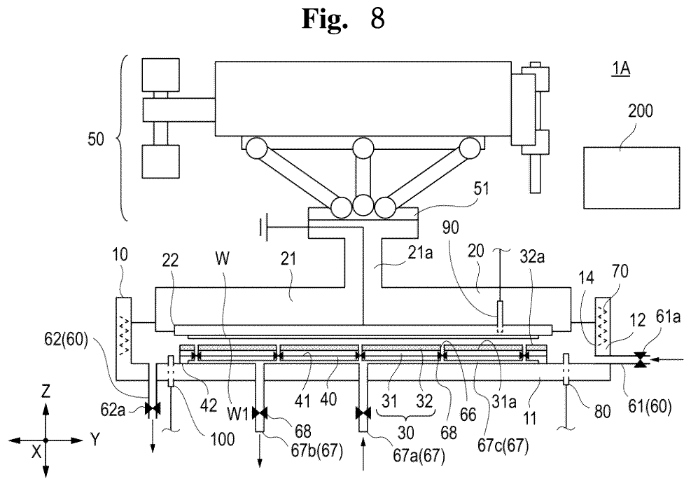

Referring to FIG. 8, the substrate processing apparatus 1A may supply processing solution through the catalyst pad 30 and the pad holder 40. That is, in addition to a supply route that supplies processing solution from the first supply unit 61, the substrate processing apparatus 1A is provided with another supply route that supplies processing solution through supply holes 66.

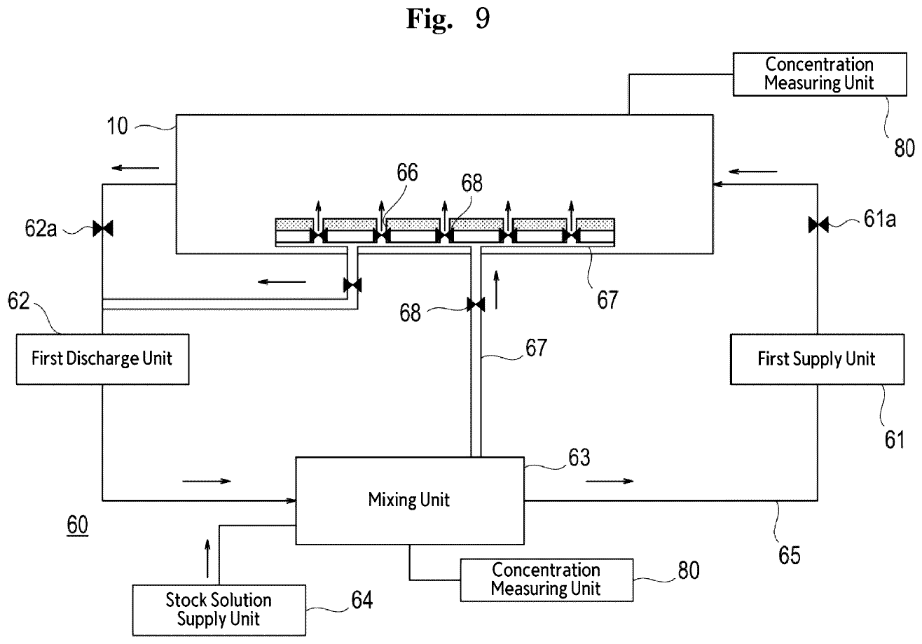

Referring to FIGS. 8 and 9, the supply and discharge unit 60 further includes the supply holes 66, a supply/discharge line 67, and flow controllers 68. The supply holes 66, the supply/discharge line 67, and the flow controllers 68 may function as a second supply and discharge unit that supplies processing solution to a substrate contact surface 32a of a catalyst layer 32 through the interior of the catalyst pad 30.

Each of the supply holes 66 is formed so as to communicate from a fixing surface 42 of the pad holder 40 to the substrate contact surface 32a of the catalyst layer 32. A plurality of supply holes 66 are formed in the catalyst pad 30 and the pad holder 40. Processing solution supplied from the supply/discharge line 67 is delivered to the substrate contact surface 32a via the supply holes 66.

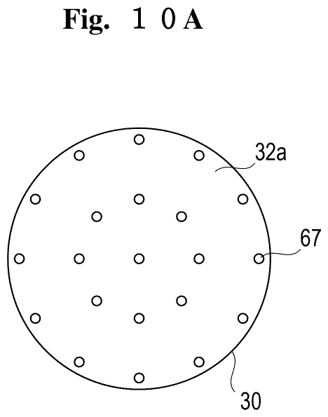

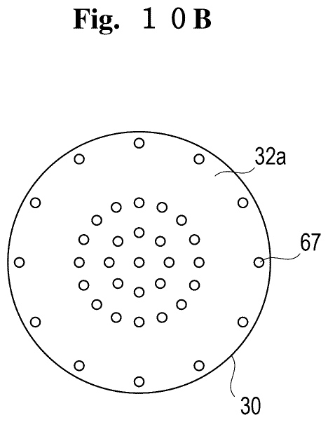

Each of the supply holes 66 may have a diameter sufficient for processing solution to flow therethrough and may be formed, for example, on the order of microns. Referring to FIG. 10A, the supply holes 66 may be formed substantially uniformly at regular intervals on the substrate contact surface 32a. Alternatively, referring to FIG. 10B, the supply holes 66 may be formed such that a central region (i.e., the region surrounded by a dotted line) on the substrate contact surface 32a is provided with a higher density of supply holes 66 than a surrounding peripheral region. The arrangement illustrated in FIG. 10B is preferable because it enables appropriate supply of processing solution to the center region, which is otherwise difficult for the processing solution to reach.

The supply/discharge line 67 includes a second supply unit 67a, a second discharge unit 67b, and a connection portion 67c. The connection portion 67c of the supply/discharge line 67 is connected to the upstream open end of each of the supply holes 66. Processing solution supplied from the mixing unit 63 is delivered to the supply holes 66 through the second supply unit 67a and the connection portion 67c. Unnecessary processing solution inside the supply/discharge line 67 is discharged from the second discharge unit 67b. The discharged processing solution returns to the mixing unit 63. The supply/discharge line 67 may be formed inside the pad holder 40 and inside a bottom portion 11 of a process chamber 10.

The flow controllers 68 are arranged at predetermined positions in the supply holes 66 and the supply/discharge line 67. The flow controllers 68 may be configured as valves that open and close. Under the control of a control unit 200, the flow controllers 68 operate so that a required amount of processing solution is supplied from the supply holes 66 to the substrate contact surface 32a.

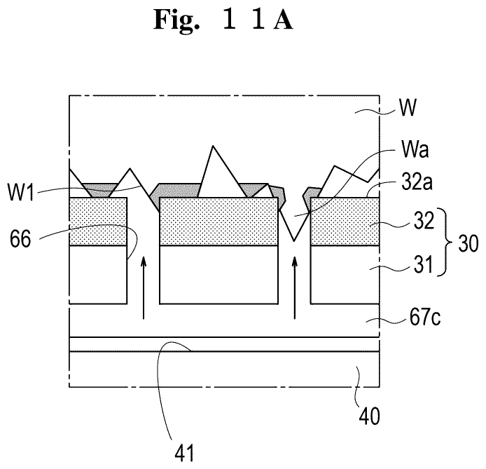

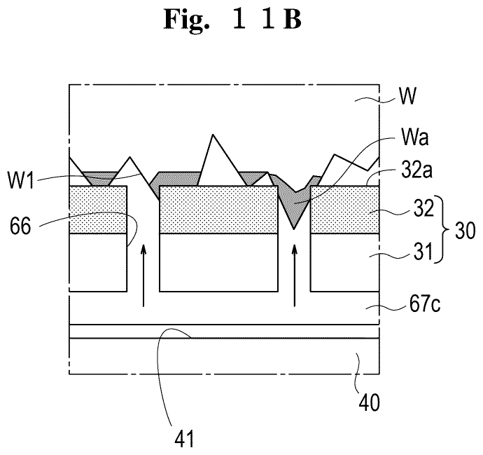

Referring to FIG. 11A, since the supply holes 66 are formed in the catalyst pad 30, the leading ends of surface irregularity portions Wa on a processing surface W1 of a substrate W may enter the supply holes 66. However, as illustrated in FIG. 11B, since processing solution at a reference concentration is appropriately supplied from the supply holes 66, surface irregularity portions Wa (in gray) that have entered the supply holes 66 may also be etched.

Since the supply holes 66 are formed in the catalyst pad 30, there is a possibility that surface irregularity portions Wa located at the opening positions of the supply holes 66 may not be etched properly during planarization. Accordingly, the substrate processing apparatus 1A performs a substrate rotation process that changes the contact position between the substrate W and the catalyst pad 30 by appropriately driving a transfer mechanism 50 under the control of a control unit 200. This substrate rotation process is performed based on measurement data from the thickness measuring unit 90.

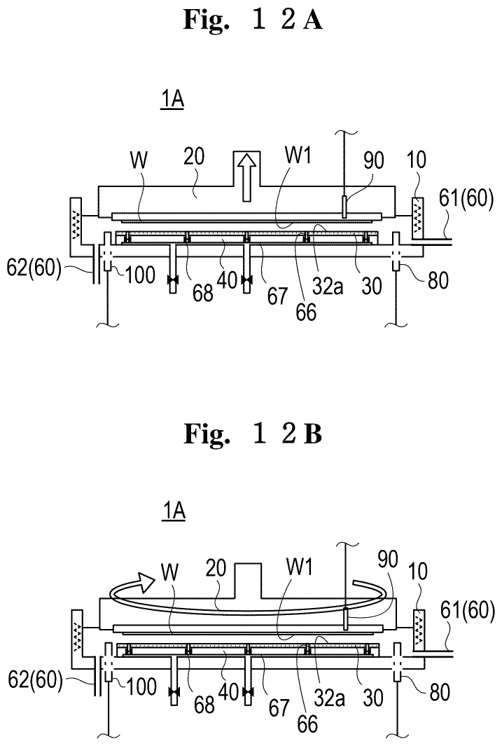

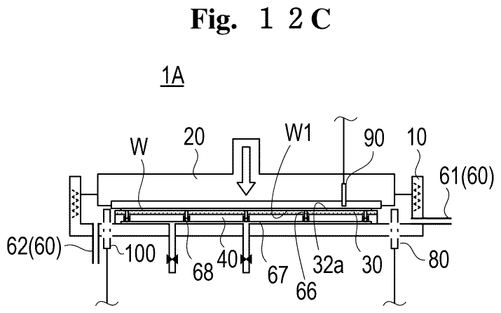

The substrate processing apparatus 1A may perform the substrate rotation process by driving a substrate holding head 20, as illustrated in FIGS. 12A to 12C.

Specifically, referring to FIG. 12A, the substrate processing apparatus 1A raises the substrate holding head 20 to separate the substrate W and the catalyst pad 30. The separation amount of the substrate holding head 20 only needs to be a distance at which the substrate W and the catalyst pad 30 are separated without hindering rotation.

Thereafter, referring to FIG. 12B, the substrate processing apparatus 1A rotates the substrate holding head 20 in a predetermined direction. At this time, the substrate processing apparatus 1A rotates the substrate holding head 20 by a predetermined rotation amount so that the surface irregularity portions Wa are brought into contact with the substrate contact surface 32a, while avoiding entry into the openings of the supply holes 66 as much as possible. The rotation amount of the substrate holding head 20 is appropriately set based on the positions of the supply holes 66 formed in the catalyst pad 30 and the size and thickness of the substrate W, so that the surface irregularity portions Wa are brought into contact with the substrate contact surface 32a.

Thereafter, referring to FIG. 12C, the substrate processing apparatus 1A lowers the rotated substrate holding head 20 to bring the substrate W into contact with the catalyst pad 30 so that a predetermined pressing force is applied to the substrate W.

As described above, in embodiments, the substrate W is rotated while out of contact with the catalyst pad 30 so that the contact position between the substrate contact surface 32a of the catalyst pad 30 and the processing surface W1 is shifted before and after rotation. Since the substrate contact surface 32a of the catalyst pad 30 has a plurality of supply holes 66, some of the surface irregularity portions Wa of the processing surface W1 may enter the openings of the supply holes 66. In this case, only some of the surface irregularity portions Wa contact the substrate contact surface 32a, and may not be properly etched. However, in the substrate processing apparatus 1A of embodiments, by rotating the substrate holding head 20 to change the contact position between the processing surface W1 and the substrate contact surface 32a, the processing surface W1 can be uniformly planarized.

The substrate processing apparatus 1A according to embodiments includes the supply and discharge unit 60 that supplies processing solution to the substrate contact surface 32a of the catalyst pad 30 through the supply holes 66 and the supply/discharge line 67. Accordingly, the substrate processing apparatus 1A can supply processing solution appropriately to both the central region and the peripheral region of the catalyst pad 30. In addition, the substrate processing apparatus 1A drives the substrate holding head 20 to change the contact position between the processing surface W1 of the substrate W and the substrate contact surface 32a of the catalyst pad 30. Thus, the substrate processing apparatus 1A can reduce etching defects of the substrate W caused by the supply holes 66.

Hereinafter, the operation of the substrate processing apparatus 1A according to embodiments will be described. A series of steps to be described below are merely exemplary, and other steps may also be included in between as necessary. In addition, the order of the steps to be described below may be changed without departing from the gist of the present disclosure.

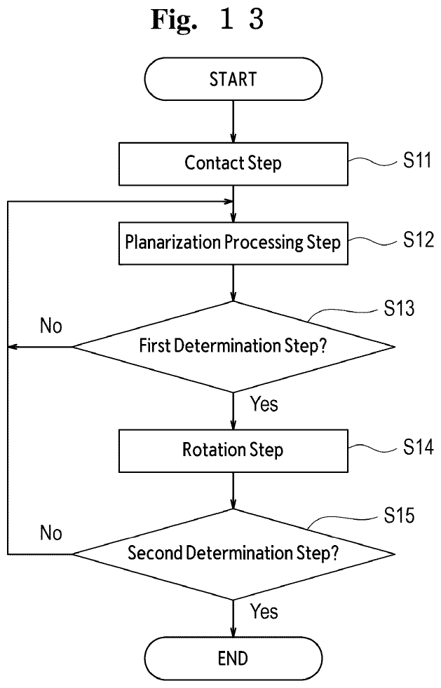

Referring to FIG. 13, as planarization processing, the substrate processing apparatus 1A performs processing that includes a contact step (S11), a planarization processing step (S12), a first determination step (S13), a rotation step (S14), and a second determination step (S15). The substrate processing apparatus 1A conducts each step under the control of the control unit 200. A predetermined amount of processing solution is supplied from the first supply unit 61 of the supply and discharge unit 60 and from the supply holes 66.

Meanwhile, the substrate processing apparatus 1A may perform a preparation step before performing the contact step (S11). The preparation step includes, for example, storing a predetermined amount of processing solution in the process chamber 10, setting the substrate W on the substrate holding head 20, and setting the catalyst pad 30 on the pad holder 40.

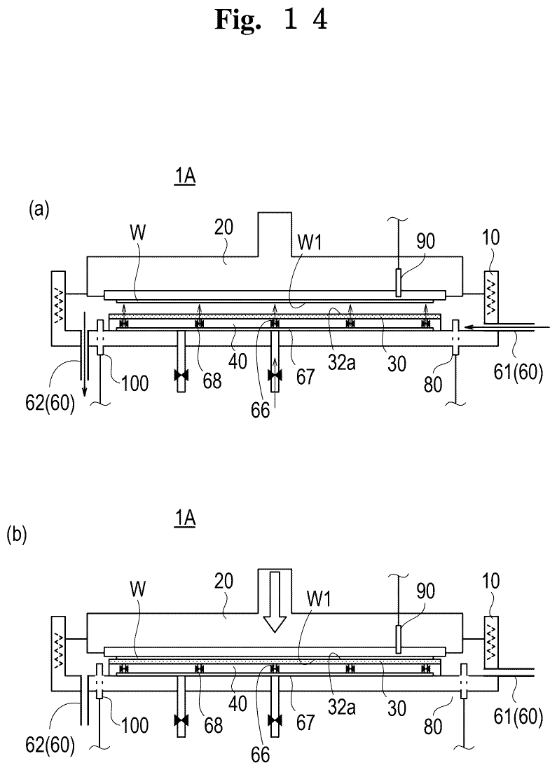

Referring to FIG. 14(a), the substrate processing apparatus 1A performs the contact step (S11). The processing surface W1 of the substrate W comes into contact with the substrate contact surface 32a of the catalyst pad 30.

Referring to FIG. 14(b), the substrate processing apparatus 1A performs the planarization processing step (S12). In the process chamber 10, the substrate W undergoes planarization while being immersed in the processing solution and in contact with the catalyst pad 30. In the planarization processing step (S12), a predetermined amount of processing solution is supplied from the first supply unit 61 and from the supply holes 66.

The substrate processing apparatus 1A performs the first determination step (S13). The control unit 200 determines the progress of etching based on the measurement data from the thickness measuring unit 90. When the control unit 200 determines that the etching amount has reached a predetermined level (S13—Yes), the processing performed by the substrate processing apparatus 1A proceeds to the rotation step (S14). Meanwhile, when the control unit 200 determines that the etching amount has not reached the predetermined level (S13—No), the control unit 200 returns to the planarization processing step (S12) so that planarization processing continues. The control unit 200 may also proceed to the rotation step (S14) at predetermined time intervals.

The substrate processing apparatus 1A performs the rotation step (S14). Referring to FIGS. 12A to 12C, the substrate processing apparatus 1A controls the transfer mechanism 50 to move the substrate holding head 20, thereby changing the contact position between the processing surface W1 of the substrate W and the substrate contact surface 32a of the catalyst pad 30. Accordingly, the surface irregularity portions Wa of the processing surface W1 come into contact with the substrate contact surface 32a at locations other than the openings of the supply holes 66, and are appropriately planarized.

The substrate processing apparatus 1A performs the second determination step (S15). The control unit 200 determines, based on the measurement data from the thickness measuring unit 90, whether the substrate W has been etched to a target thickness. When the control unit 200 determines that the substrate W has been etched to the target thickness (S15—Yes), the processing performed by the substrate processing apparatus 1A ends. Meanwhile, when the control unit 200 determines that the substrate W has not been etched to the target thickness (S15—No), the control unit 200 returns to the planarization processing step (S12) so that planarization processing continues.

Hereinafter, substrate processing apparatuses according to modified examples of the present disclosure will be described. The modified examples to be described below may be appropriately combined with the aforementioned embodiments. The modified examples to be described below may also be employed in combination without departing from the gist of the present disclosure.

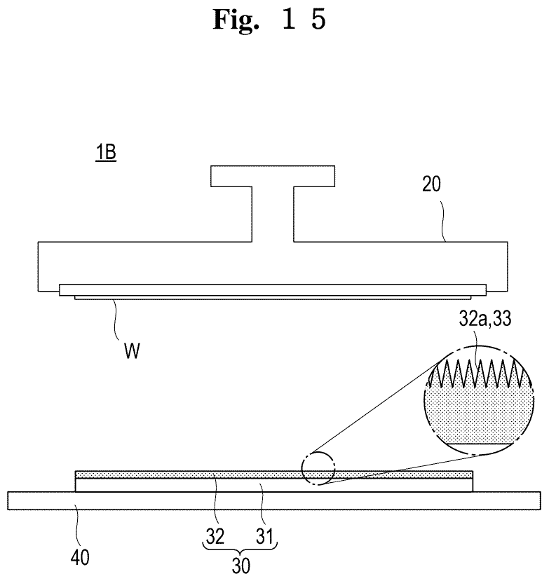

A substrate processing apparatus 1B according to Modified Example 1 will hereinafter be described. Referring to FIG. 15, the substrate processing apparatus 1B may form a transfer pattern 33 of a predetermined shape on a substrate contact surface 32a of a catalyst pad 30 and transfer the transfer pattern 33 onto a substrate W.

The transfer pattern 33 is formed on the surface of the substrate contact surface 32a of the catalyst layer 32. When etching is performed during planarization processing, the transfer pattern 33 is transferred onto a processing surface W1 of the substrate W. The shape of the transfer pattern 33 may be formed arbitrarily according to the use of the substrate W. For example, as illustrated in FIG. 15, the transfer pattern 33 may be formed as an uneven pattern.

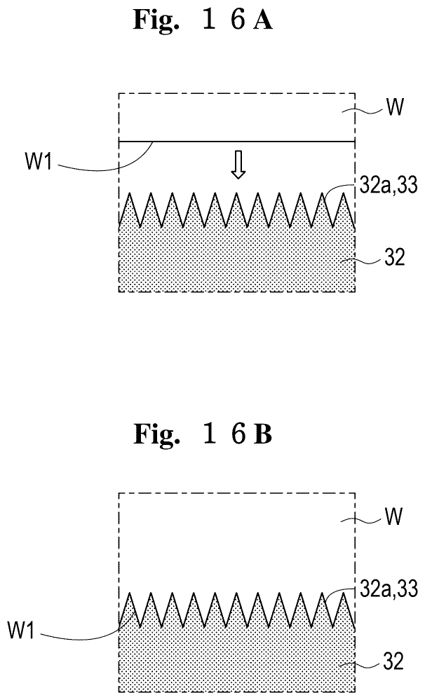

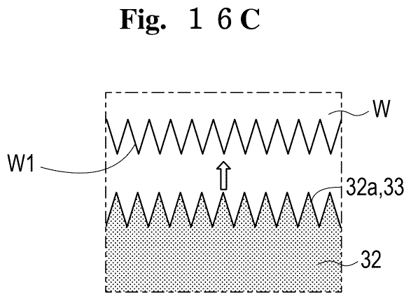

Referring to FIG. 16A, when transferring the transfer pattern 33 formed on the catalyst pad 30, the substrate processing apparatus 1B brings the processing surface W1 into contact with the substrate contact surface 32a. Referring to FIG. 16B, the processing surface W1 is gradually etched along the outline of the transfer pattern 33. Referring to FIG. 16C, when the processing surface W1 has been etched in accordance with the outline of the transfer pattern 33, the substrate processing apparatus 1B separates the substrate W from the catalyst pad 30. Accordingly, the transfer pattern 33 is transferred onto the processing surface W1 of the substrate W.

When Modified Example 1 is employed in the substrate processing apparatus 1A, the substrate holding head 20 may be rotated to change the transfer position of the transfer pattern 33 during etching, enabling various patterning operations with higher precision.

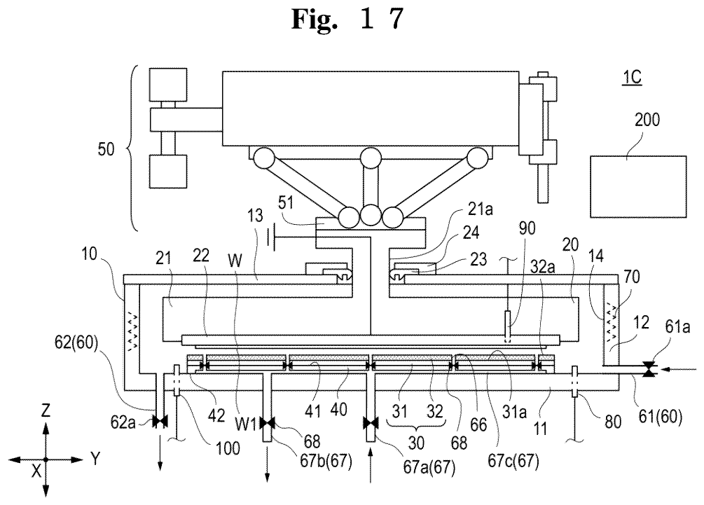

A substrate processing apparatus 1C according to Modified Example 2 will hereinafter be described. Referring to FIG. 17, the substrate processing apparatus 1C is a form in which gas is used as processing solution to planarize a processing surface W1 of a substrate W.

Referring to FIG. 17, the substrate processing apparatus 1C uses a gaseous processing solution in a process chamber 10. For example, vapor of aqueous hydrofluoric acid may be used as the processing solution. The substrate processing apparatus 1C includes a cover portion 13 for sealing and accommodating the gaseous processing solution in the process chamber 10. As illustrated in FIG. 17, a shaft portion 21a of a head body 21 of a substrate holding head 20 is arranged to pass through the cover portion 13 of the process chamber 10. A sealing member 23 is arranged around the shaft portion 21a. The sealing member 23 is fixed by a sealing holder 24. In this manner, the process chamber 10 has its receiving portion 14 sealed by the cover portion 13 and the sealing member 23, so that the processing solution does not leak to the outside.

The substrate processing apparatus 1C differs from the substrate processing apparatuses 1 and 1A in that the processing solution handled by a supply and discharge unit 60 is a gas rather than a liquid, but the functions of the supply and discharge unit 60 may be the same as in the substrate processing apparatuses 1 and 1A.

The substrate processing apparatus 1C is configured to be able to move a substrate holding head 20 in a predetermined direction while maintaining the interior of the process chamber 10 to be sealed by the cover portion 13 and the sealing member 23. Accordingly, even when gas is used as the processing solution, the substrate processing apparatus 1C may perform planarization processing in the same manner as the substrate processing apparatuses 1 and 1A.

As described above, the substrate processing apparatus 1A is an apparatus that planarizes the processing surface W1 of the substrate W to be processed by etching inside the process chamber 10, and includes: the substrate holding head 20; the substrate holder 22 provided on the substrate holding head 20 and holding the substrate W; the base material 31; the catalyst pad 30 including the catalyst layer 32 having the substrate contact surface 32a formed on a surface of the base material 31 facing the substrate W, the substrate contact surface 32a contacting the processing surface W1 of the substrate W; the pad holder 40 that fixedly holds the catalyst pad 30 inside the process chamber 10; the supply and discharge unit 60 that supplies at least an etching processing solution into the process chamber 10; the transfer mechanism 50 that relatively moves the substrate holding head 20 at least in the contact/separation direction in which the substrate holding head 20 approaches and separates from the catalyst pad 30; and the control unit 200. The substrate contact surface 32a of the catalyst pad 30 has an area larger than that of the processing surface W1, and, in the presence of processing solution supplied into the process chamber 10, the supply and discharge unit 60 supplies fresh processing solution to the substrate contact surface 32a while the processing surface W1 of the substrate W is being pressed against the substrate contact surface 32a of the catalyst pad 30.

With this configuration, when the substrate W is etched using a catalyst-based etching technique by means of the catalyst pad 30, the substrate processing apparatus 1A can supply processing solution over the entire contact surface between the substrate W and the catalyst pad 30. As a result, the substrate processing apparatus 1A can not only shorten processing time but also appropriately etch the substrate W. In addition, since the substrate processing apparatus 1A performs etching while maintaining the contact state between the substrate W and the catalyst pad 30, scratches or the like do not occur. Furthermore, since, in the substrate processing apparatus 1A, the area of the substrate contact surface 32a is larger than the area of the processing surface W1, the entire processing surface W1 can be etched at once, thereby improving productivity.

What is claimed is:

1. A substrate processing apparatus that etches a processing surface of a substrate to be processed inside a process chamber, comprising:
a substrate holding head;
a substrate holder provided on the substrate holding head and configured to hold the substrate;
a catalyst pad including a base material and a catalyst layer formed on a surface of the base material facing the substrate, the catalyst layer having a substrate contact surface that contacts the processing surface of the substrate;
a pad holder configured to fixedly hold the catalyst pad inside the process chamber;
a supply and discharge unit configured to supply at least an etching processing solution into the process chamber;
a transfer mechanism configured to relatively move the substrate holding head with respect to the catalyst pad in a contact/separation direction along which the substrate holding head approaches and separates from the catalyst pad; and
a control unit,
wherein:
the catalyst pad has a substrate contact surface whose area is larger than that of the processing surface, and
the supply and discharge unit supplies fresh processing solution to the substrate contact surface while the processing surface of the substrate is pressed against the substrate contact surface of the catalyst pad, in the presence of the processing solution supplied into the process chamber.

2. The substrate processing apparatus of claim 1, wherein the substrate holding head is fixed in position while the processing surface of the substrate is in contact with the substrate contact surface of the catalyst layer.

3. The substrate processing apparatus of claim 1, wherein a flatness of the substrate contact surface is greater than a flatness of the processing surface.

4. The substrate processing apparatus of claim 1, wherein the supply and discharge unit includes: a first supply and discharge unit that supplies the processing solution into the process chamber; and a second supply and discharge unit that supplies the processing solution to the substrate contact surface through an interior of the catalyst pad.

5. The substrate processing apparatus of claim 4, wherein:
the pad holder has a fixing surface fixed to the process chamber, and
the second supply and discharge unit includes: a plurality of supply holes communicating with the substrate contact surface and the fixing surface; a supply/discharge line that supplies the processing solution to the supply holes; and a flow controller that controls an amount of processing solution supplied to the supply holes.

6. The substrate processing apparatus of claim 1, wherein the substrate holding head is provided with a thickness measuring unit that measures a thickness of the substrate.

7. The substrate processing apparatus of claim 1, wherein the transfer mechanism includes an adjustment drive unit that moves the substrate holding head substantially in the contact/separation direction, in a planar direction substantially orthogonal to the contact/separation direction, and in a rotational direction using the contact/separation direction as a rotation axis.

8. The substrate processing apparatus of claim 7, wherein the control unit moves the substrate holding head in a separation direction to separate the substrate contact surface from the processing surface, then moves the substrate holding head substantially in at least one of the planar direction and the rotational direction, and then moves the substrate holding head in a contact direction to bring the substrate contact surface into contact with the processing surface.

9. The substrate processing apparatus of claim 7, wherein:
a predetermined transfer pattern is formed on the substrate contact surface, and
the control unit drives the transfer mechanism so that an arbitrary pattern shape corresponding to the transfer pattern is formed on the processing surface.

10. The substrate processing apparatus of claim 1, further comprising:
a conditioning mechanism that conditions the substrate contact surface of the catalyst pad.

11. The substrate processing apparatus of claim 1, wherein the catalyst layer is formed of a precious metal or a carbon material.

12. The substrate processing apparatus of claim 6, wherein the control unit controls an amount of processing solution supplied from the supply and discharge unit based on thickness information of the substrate measured by the thickness measuring unit.

13. A substrate processing apparatus comprising:
a process chamber;
a catalyst pad arranged on a bottom surface of the process chamber and including a catalyst layer having a substrate contact surface;
a substrate holder arranged on the catalyst pad and configured to hold a substrate having a processing surface;
a supply and discharge unit configured to supply etching processing solution into the process chamber and discharge used processing solution; and
a control unit,
wherein:
the catalyst pad has a substrate contact surface whose area is larger than that of the processing surface, and
the control unit performs control such that with the processing surface of the substrate in contact with the substrate contact surface of the catalyst pad, surface irregularity portions of the substrate are removed to achieve planarization by being immersed in the processing solution within the process chamber.

14. The substrate processing apparatus of claim 13, wherein the supply and discharge unit includes: a first supply and discharge unit that supplies the processing solution into the process chamber; and a second supply and discharge unit that supplies the processing solution to the substrate contact surface through an interior of the catalyst pad.

15. The substrate processing apparatus of claim 14, wherein the first supply and discharge unit comprises: a first supply unit connected to a sidewall of the process chamber; and a first discharge unit connected to the bottom surface of the process chamber.

16. The substrate processing apparatus of claim 14, further comprising:
a pad holder that fixedly holds the catalyst pad inside the process chamber, the pad holder having a fixing surface fixed to the process chamber,
wherein the second supply and discharge unit includes: a plurality of supply holes communicating with the substrate contact surface and the fixing surface; a supply/discharge line that supplies the processing solution to the supply holes; and a flow controller that controls an amount of processing solution supplied to the supply holes.

17. The substrate processing apparatus of claim 16, wherein:
the substrate contact surface includes a central region and a peripheral region surrounding the central region, and
a higher density of supply holes is arranged in the central region than in the peripheral region.

18. The substrate processing apparatus of claim 14, further comprising:
a pad holder on which the catalyst pad is placed;
a substrate holding head including the substrate holder and a head body, and arranged at a position facing the pad holder; and
a transfer mechanism that relatively moves the substrate holding head with respect to the catalyst pad in a contact/separation direction in which the substrate holding head approaches and separates from the catalyst pad.

19. The substrate processing apparatus of claim 14, further comprising:
a conditioning mechanism that conditions the substrate contact surface of the catalyst pad.

20. A substrate processing apparatus comprising:
a substrate holding head;
a substrate holder provided on the substrate holding head and configured to hold a substrate;
a catalyst pad including a base material and a catalyst layer formed on a surface of the base material facing the substrate, the catalyst layer having a substrate contact surface that contacts a processing surface of the substrate;
a supply and discharge unit configured to supply at least an etching processing solution into a process chamber;
a transfer mechanism configured to relatively move the substrate holding head with respect to the catalyst pad in a contact/separation direction in which the substrate holding head approaches and separates from the catalyst pad; and
a control unit configured to control the supply and discharge unit and the transfer mechanism,
wherein:
the substrate contact surface of the catalyst pad has an area larger than that of the processing surface,
the supply and discharge unit supplies fresh processing solution to the substrate contact surface while the processing surface of the substrate is pressed against the substrate contact surface of the catalyst pad in the presence of the processing solution supplied into the process chamber,
the substrate holding head is fixed in position while the processing surface of the substrate is in contact with the substrate contact surface of the catalyst layer,
the transfer mechanism includes an adjustment drive unit that moves the substrate holding head substantially in the contact/separation direction, in a planar direction substantially orthogonal to the contact/separation direction, and in a rotational direction using the contact/separation direction as a rotation axis,
the control unit moves the substrate holding head in a separation direction to separate the substrate contact surface from the processing surface, then moves the substrate holding head substantially in at least one of the planar direction and the rotational direction, and then moves the substrate holding head in a contact direction to bring the substrate contact surface into contact with the processing surface,
the substrate contact surface has a predetermined transfer pattern formed thereon, and
the control unit drives the transfer mechanism such that an arbitrary pattern shape corresponding to the transfer pattern is formed on the processing surface.
